(19) United States
(12) Patent Application Publication
(10) Pub. No.: US 2025/0176345 A1
(43) Pub. Date: May 29, 2025

(54) DISPLAY DEVICE

(71) Applicant: ELECTRONICS AND TELECOMMUNICATIONS RESEARCH INSTITUTE, Daejeon (KR)

(72) Inventors: WOOSEUP YOUM, Daejeon (KR); Kukjoo KIM, Daejeon (KR); DAE HYUN AHN, Daejeon (KR); Hyunsu CHO, Daejeon (KR); Chul Woong JOO, Daejeon (KR)

(21) Appl. No.: 18/962,972

(22) Filed: Nov. 27, 2024

(30) Foreign Application Priority Data
Nov. 29, 2023 (KR) 10-2023-0169943
Nov. 15, 2024 (KR) 10-2024-0163156

(51) Int. Cl. H01L 27/15; H01L 33/60

(52) U.S. Cl. CPC H10H 29/142; H10H 20/856

(57) ABSTRACT

Provided is a display device including: a first pixel configured to emit a first optical signal, a second pixel disposed adjacent to the first pixel in a first direction and configured to emit a second optical signal, a third pixel configured to emit a third optical signal, a fourth pixel disposed adjacent to the third pixel in the first direction and configured to emit a fourth optical signal, and an optical part configured to reflect the first to fourth optical signals. The second pixel and the third pixel are disposed between the first pixel and the fourth pixel, the first optical signal and the third optical signal are emitted from a first region of the optical part, the second optical signal and the fourth optical signal are emitted from a second region of the optical part, and the first region and the second region are spaced apart from each other.

### CROSS-REFERENCE TO RELATED APPLICATIONS

This U.S. non-provisional patent application claims priority under 35 U.S.C. § 119 of Korean Patent Application No. 10-2023-0169943, filed on Nov. 29, 2023 and Korean Patent Application No. 10-2024-0163156, filed on Nov. 15, 2024, the entire contents of which are hereby incorporated by reference.

### BACKGROUND

The present disclosure herein relates to a display device, and more particularly, to a display device including an optical part overlapping a pixel array.

Display devices are devices for displaying images on electronic devices such as smartphones, laptops, and navigation systems. Such a display device generates an image and provides the generated image to a user through a screen.

Recently, electronic devices based on mobility are being widely used. Thus, various studies are being conducted on display devices that are capable of being miniaturized.

### SUMMARY

The present disclosure provide a display device having improved integration.

An embodiment of the inventive concept provides a display device including: a first pixel configured to emit a first optical signal; a second pixel disposed adjacent to the first pixel in a first direction and configured to emit a second optical signal; a third pixel configured to emit a third optical signal; a fourth pixel disposed adjacent to the third pixel in the first direction and configured to emit a fourth optical signal; and an optical part configured to reflect the first to fourth optical signals, wherein the second pixel and the third pixel are disposed between the first pixel and the fourth pixel, the first optical signal and the third optical signal are emitted from a first region of the optical part, the second optical signal and the fourth optical signal are emitted from a second region of the optical part, and the first region and the second region are spaced apart from each other.

In an embodiment of the inventive concept, a display device includes: a first pixel configured to emit a first optical signal; a second pixel disposed adjacent to the first pixel in a first direction and configured to emit a second optical signal; a third pixel configured to emit a third optical signal; a fourth pixel disposed adjacent to the third pixel in the first direction and configured to emit a fourth optical signal; and an optical part configured to reflect the first to fourth optical signals, wherein the second pixel and the third pixel are disposed between the first pixel and the fourth pixel, wherein the optical part includes: a first reflector that overlaps the first pixel and the second pixel and is spaced apart from the first pixel and the second pixel in the second direction; and a second reflector that overlaps the third pixel in the second direction and is spaced apart from the third pixel and the fourth pixel in the second direction, wherein the second direction intersects the first direction.

In an embodiment of the inventive concept, a display device includes: a substrate; a first pixel, a second pixel, a third pixel, a fourth pixel, a fifth pixel, and a sixth pixel, which are disposed on the substrate; and a first outer pixel, a second outer pixel, a third outer pixel, a fourth outer pixel, a fifth outer pixel, and a sixth outer pixel, wherein the first pixel and the second pixel are disposed between the first outer pixel and the second outer pixel, the third pixel and the fourth pixel are disposed between the third outer pixel and the fourth outer pixel, the fifth pixel and the sixth pixel are disposed between the fifth outer pixel and the sixth outer pixel, the second outer pixel and the third outer pixel are adjacent to each other in a first direction, the fourth outer pixel and the fifth outer pixel are adjacent to each other in the first direction, each of the first and second pixels is configured to emit an optical signal including light in a second wavelength range, each of the third and fourth pixels is configured to emit an optical signal including light in a second wavelength range, and each of the fifth and sixth pixels is configured to emit an optical signal including light in a third wavelength range.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a plan view of a display device according to some embodiments;

FIG. 1B is a cross-sectional view taken along line I-I′ of FIG. 1A;

FIG. 2 is a cross-sectional view of a display device according to some embodiments;

FIG. 3A is a cross-sectional view of a display device according to some embodiments;

FIG. 3B is an enlarged view of an area A of FIG. 3A;

FIG. 4A is a plan view of a display device according to some embodiments;

FIG. 4B is a cross-sectional view taken along line II-II′ of FIG. 4A;

FIG. 4C is an enlarged view of an area B of FIG. 4B;

FIG. 4D is a view illustrating a combiner of the display device according to some embodiments;

FIG. 4E is a view illustrating an operation of the display device according to some embodiments; and

FIG. 4F is a view illustrating an operation of the display device

according to some embodiments.

### DETAILED DESCRIPTION

Hereinafter, a display device according to embodiments of the inventive concept will be described in detail with reference to the drawings.

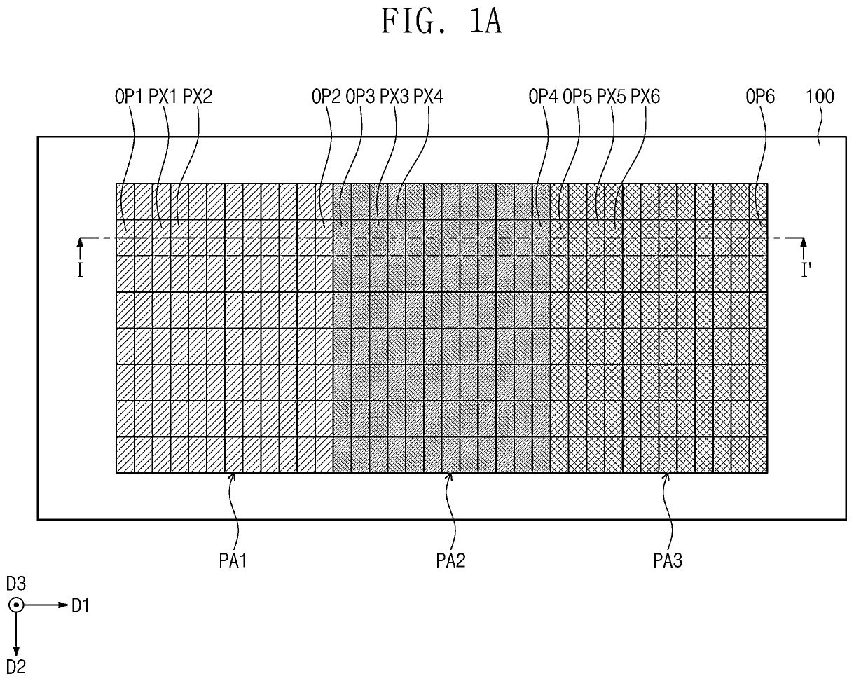

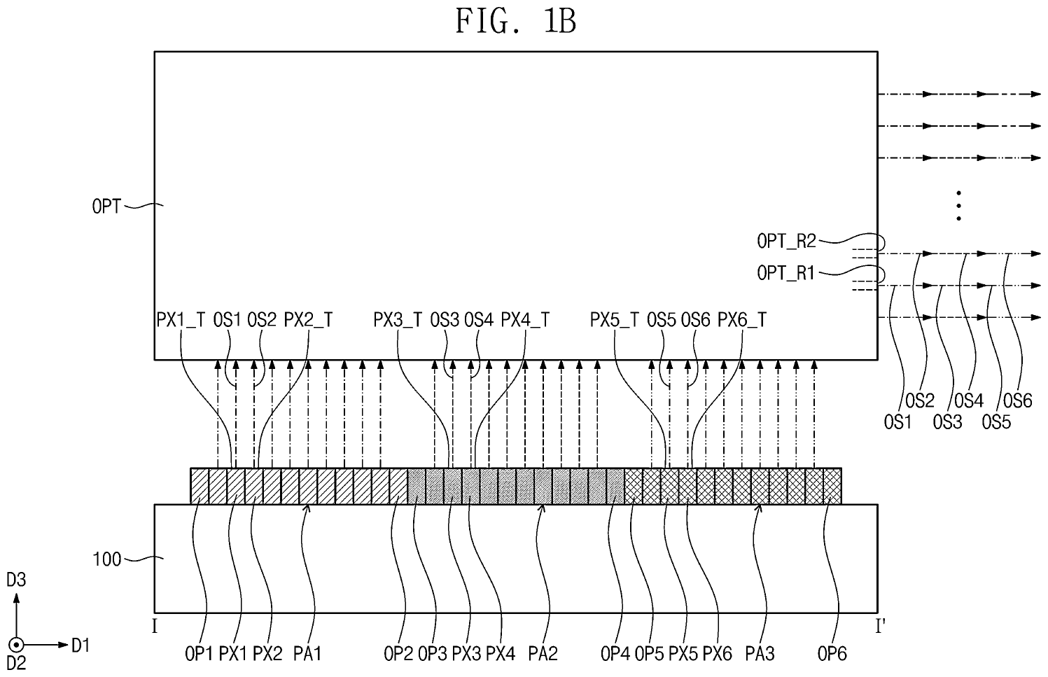

FIG. 1A is a plan view of a display device according to some embodiments. FIG. 1B is a cross-sectional view taken along line I-I′ of FIG. 1A.

Referring to FIGS. 1A and 1B, a substrate 100 may be provided. The

substrate 100 may have the form of a plate extending along a plane defined by a first direction D1 and a second direction D2. The first direction D1 and the second direction D2 may intersect each other. For example, the first direction D1 and the second direction D2 may be horizontal directions that are orthogonal to each other.

In some embodiments, the substrate 100 may be a semiconductor substrate. For example, the substrate 100 may include silicon, germanium, silicon-germanium, GaP, or GaAs. In some embodiments, the substrate 100 may be a semiconductor substrate on which a circuit layer including a CMOS circuit is disposed. In some embodiments, the circuit layer may include data lines, scan lines, capacitors, and transistors.

A first pixel array PA1, a second pixel array PA2, and a third pixel array PA3 may be disposed on the substrate 100. The first to third pixel arrays PA1, PA2, and PA3 may be arranged in the first direction D1.

Each of the first to third pixel arrays PA1, PA2, and P3 may include a plurality of pixels arranged in the first direction D1 and the second direction D2. Each of the first to third pixel arrays PA1, PA2, and PA3 may include a plurality of outer pixels. The outer pixels may be pixels disposed at the outermost portion of each of the first to third pixel arrays PA1, PA2, and PA3. The outer pixels may surround at least one pixel.

The first pixel array PA1 may include a first pixel PX1 and a second pixel PX2. The second pixel array PA2 may include a third pixel PX3 and a fourth pixel PX4. The third pixel array PA3 may include a fifth pixel PX5 and a sixth pixel PX6.

The first pixel array PA1 may include a first outer pixel OP1 and a second outer pixel OP2. The second pixel array PA2 may include a third outer pixel OP3 and a fourth outer pixel OP4. The third pixel array PA3 may include a fifth outer pixel OP5 and a sixth outer pixel OP6.

The first outer pixel OP1 and the second outer pixel OP2 may be spaced apart from each other in the first direction D1. The third outer pixel OP3 and the fourth outer pixel OP4 may be spaced apart from each other in the first direction D1. The fifth outer pixel OP5 and the sixth outer pixel OP6 may be spaced apart from each other in the first direction D1.

The first pixel PX1 and the second pixel PX2 may be disposed between the first outer pixel OP1 and the second outer pixel OP2. The third pixel PX3 and the fourth pixel PX4 may be disposed between the third outer pixel OP3 and the fourth outer pixel OP4. The fifth pixel PX5 and the sixth pixel PX6 may be disposed between the fifth outer pixel OP5 and the sixth outer pixel OP6.

The second pixel PX2 and the third pixel PX3 may be disposed between the first pixel PX1 and the fourth pixel PX4. The fourth pixel PX4 and the fifth pixel PX5 may be disposed between the third pixel PX3 and the sixth pixel PX6.

The first pixel PX1 and the second pixel PX2 may be adjacent to each other in the first direction D1. The third pixel PX3 and the fourth pixel PX4 may be adjacent to each other in the first direction D1. The fifth pixel PX5 and the sixth pixel PX6 may be adjacent to each other in the first direction D1.

A top surface PX1_T of the first pixel PX1 and a top surface PX2_T of the second pixel PX2 may define a coplanar surface. A top surface PX3_T of the third pixel PX3 and a top surface PX4_T of the fourth pixel PX4 may define a coplanar surface. A top surface PX5_T of the fifth pixel PX5 and a top surface PX6_T of the sixth pixel PX6 may define a coplanar surface.

The second outer pixel OP2 and the third outer pixel OP3 may be adjacent to each other in the first direction D1. The fourth outer pixel OP4 and the fifth outer pixel OP5 may be adjacent to each other in the first direction D1.

An optical part OPT may be disposed at a level higher than that of each of the first to third pixel arrays PA1, PA2, and PA3. The optical part OPT may be spaced apart from each of the first to third pixel arrays PA1, PA2, and PA3 in a third direction D3. The third direction D3 may intersect the first direction DI and the second direction D2. For example, the third direction D3 may be a vertical direction that is orthogonal to the first direction D1 and the second direction D2.

The optical part OPT may overlap the first to third pixel arrays PA1, PA2, and PA3 in the third direction D3.

The first pixel PX1 may emit a first optical signal OS1 in the third direction D3. The second pixel PX2 may emit a second optical signal OS2 in the third direction D3. The first optical signal OS1 and the second optical signal OS2 may include light in the first wavelength range.

The third pixel PX3 may emit a third optical signal OS3 in the third direction D3. The fourth pixel PX4 may emit a fourth optical signal OS4 in the third direction D3. The third optical signal OS3 and the fourth optical signal OS4 may include light in the second wavelength range.

The fifth pixel PX5 may emit a fifth optical signal OS5 in the third direction D3. The sixth pixel PX6 may emit a sixth optical signal OS6 in the third direction D3. The fifth optical signal OS5 and the sixth optical signal OS6 may include light in a third wavelength range.

In some embodiments, each of the first wavelength region, the second wavelength region, and the third wavelength region may be one of red, blue, and green wavelength regions. For example, the first wavelength range may be a red wavelength range, the second wavelength range may be a blue wavelength range, and the third wavelength range may be a green wavelength range.

The first to sixth optical signals OS1, OS2, OS3, OS4, OS5, and OS6 may be incident onto the optical part OPT. The first to sixth optical signals OS1, OS2, OS3, OS4, OS5, and OS6 incident onto the optical part OPT may proceed in the third direction D3.

The optical part OPT may reflect and emit the first to sixth optical signals OS1, OS2, OS3, OS4, OS5, and OS6 that are incident thereon. The first to sixth optical signals OS1, OS2, OS3, OS4, OS5, and OS6 emitted from the optical part OPT may proceed in the first direction D1.

The first optical signal OS1, the third optical signal OS3, and the fifth optical signal OS5, which are emitted from the optical part OPT, may be emitted from the first region OPT_R1 of the optical part OPT. The first optical signal OS1, the third optical signal OS3, and the fifth optical signal OS5, which are emitted from the optical part OPT, may be emitted at the same level.

The second optical signal OS2, the fourth optical signal OS4, and the sixth optical signal OS6, which are emitted from the optical part OPT, may be emitted from the second region OPT_R2 of the optical part OPT. The second optical signal OS2, the fourth optical signal OS4, and the sixth optical signal OS6, which are emitted from the optical part OPT, may be emitted at the same level. In some embodiments, the second region OPT_R2 of the optical part OPT may be disposed at a level higher than that of the first region OPT_R1. The first region OPT_R1 and the second region OPT_R2 of the optical part OPT may be spaced apart from each other in the third direction D3.

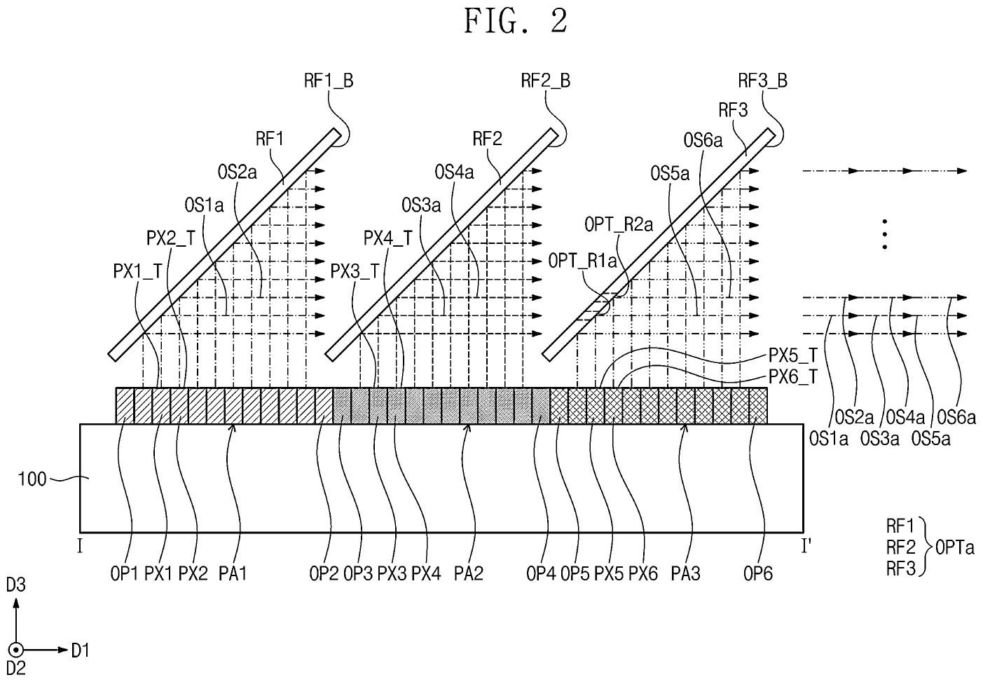

FIG. 2 is a cross-sectional view of a display device according to some embodiments. A display device of FIG. 2 may be similar to the display device of FIGS. 1A and 1B except as described below.

Referring to FIG. 2, an optical part OPTa may include a first reflector RF1, a second reflector RF2, and a third reflector RF3. The second reflector RF2 may be disposed between the first reflector RF1 and the third reflector RF3. The first reflector RF1, the second reflector RF2, and the third reflector RF3 may be spaced apart from each other.

The first reflector RF1 may overlap the first pixel array PA1 in the third direction D3. The first reflector RF1 may overlap the first pixel PX1 and the second pixel PX2 in the third direction D3. The second reflector RF2 may overlap the second pixel array PA2 in the third direction D3. The second reflector RF2 may overlap the third pixel PX3 and the fourth pixel PX4 in the third direction D3. The third reflector RF3 may overlap the third pixel array PA3 in the third direction D3. The third reflector RF3 may overlap the fifth pixel PX5 and the sixth pixel PX6 in the third direction D3.

A bottom surface RF1_B of the first reflector RF1 may be inclined with respect to a top surface of the substrate 100. The bottom surface RF1_B of the first reflector RF1 may be inclined with respect to a top surface PX1_T of the first pixel PX1 and a top surface PX2_T of the second pixel PX2. A bottom surface RF2_B of the second reflector RF2 may be inclined with respect to the top surface of the substrate 100. The bottom surface RF2_B of the second reflector RF2 may be inclined with respect to a top surface PX3_T of the third pixel PX3 and a top surface PX4_T of the fourth pixel PX4. A bottom surface RF3_B of the third reflector RF3 may be inclined with respect to the top surface of the substrate 100. The bottom surface RF3_B of the third reflector RF3 may be inclined with respect to a top surface PX5_T of the fifth pixel PX5 and a top surface PX6_T of the sixth pixel PX6.

In some embodiments, each of the first to third reflectors RF1, RF2, and RF3 may include a splitter. In some embodiments, the first reflector RF1 may include a mirror, and each of the second reflector RF2 and the third reflector RF3 may include a splitter. In some embodiments, each of the first to third reflectors RF1, RF2, and RF3 may include a dichroic mirror. For example, the first reflector RF1 may reflect light in a first wavelength range, the second reflector RF2 may reflect light in a second wavelength range, and the third reflector RF3 may reflect light in a third wavelength range.

The first pixel PX1 may emit a first optical signal OS1a. The second pixel PX2 may emit a second optical signal OS2a. The third pixel PX3 may emit a third optical signal OS3a. The fourth pixel PX4 may emit a fourth optical signal OS4a. The fifth pixel PX5 may emit a fifth optical signal OS5a. The sixth pixel PX6 may emit a sixth optical signal OS6a.

The first reflector RF1 may reflect the first optical signal OS1a and the second optical signal OS2a. The first reflector RF1 may reflect the first optical signal OS1a and the second optical signal OS2a to emit the first and second optical signals OS1a and OS2a in the first direction D1. The second reflector RF2 may reflect the third optical signal OS3a and the fourth optical signal OS4a. The second reflector RF2 may reflect the third optical signal OS3a and the fourth optical signal OS4a to emit the third and fourth optical signals OS3a and OS4a in the first direction D1. The third reflector RF3 may reflect the fifth optical signal OS5a and the sixth optical signal OS6a. The third reflector RF3 may reflect the fifth optical signal OS5a and the sixth optical signal OS6a to emit the fifth and sixth optical signals OSSa and OS6a in the first direction D1.

Levels of regions from which the first optical signal OS1a, the third optical signal OS3a, and the fifth optical signal OS5a are reflected by the first to third reflectors RF1, RF2, and RF3 may be the same. Levels of regions from which the second optical signal OS2a, the fourth optical signal OS4a, and the sixth optical signal OS6a are reflected by the first to third reflectors RF1, RF2, and RF3 may be the same.

The first optical signal OS1a and the second optical signal OS2a may be transmitted through the second reflector RF2 and the third reflector RF3. The third optical signal OS3a and the fourth optical signal OS4a may be transmitted through the third reflector RF3.

The first optical signal OS1a, the third optical signal OS3a, and the fifth optical signal OS5a may be emitted from a first region OPT_R1a of the third reflector RF3. The second optical signal OS2a, the fourth optical signal OS4a, and the sixth optical signal OS6a may be emitted from a second region OPT_R2a of the third reflector RF3. The first region OPT_R1a and the second region OPT_R2a of the third reflector RF3 may be similar to the first region OPT_R1 and the second region OPT_R2 of the optical part OPT of FIG. 1B. The first region OPT_R1a and the second region OPT_R2a of the third reflector RF3 may be spaced apart from each other in the third direction D3.

The display device according to some embodiments may include an optical part OPTa to emit the first, third and fifth optical signals OS1a, OS3a, and OS5a from the first region OPT_R1a of the third reflector RF3. In addition, the second, fourth, and sixth optical signals OS2a, OS4a, and OS6a may be emitted from the second region OPT_R2a of the third reflector RF3. Thus, pixels that emit light in the same wavelength range may be disposed adjacent to each other. Thus, a process of forming the pixels on the substrate 100 may be simplified.

The display device according to some embodiments may include first to third reflectors RF1, RF2, and RF3, each of which includes a splitter, so that an optical signal reflected from the first reflector RF1 is transmitted through the second reflector RF2 and the third reflector RF3 to proceed.

In the display device according to some embodiments, outer pixels that do not emit the optical signals may be disposed outside the first to third pixel arrays PA1, PA2, and PA3, and the outer pixels may be adjacent to each other to facilitate an alignment between the first to third pixel arrays PA1, PA2, and PA3 and the optical part OPT.

In the display device according to some embodiments may include first to third reflectors RF1, RF2, and RF3, each of which includes a dichroic mirror, so that an intensity of an optical signal reflected from the first reflector RF1 and transmitted through the second reflector RF2 or the third reflector RF3 and an intensity of an optical signal reflected from the second reflector RF2 and transmitted through the third reflector RF3 are relatively large.

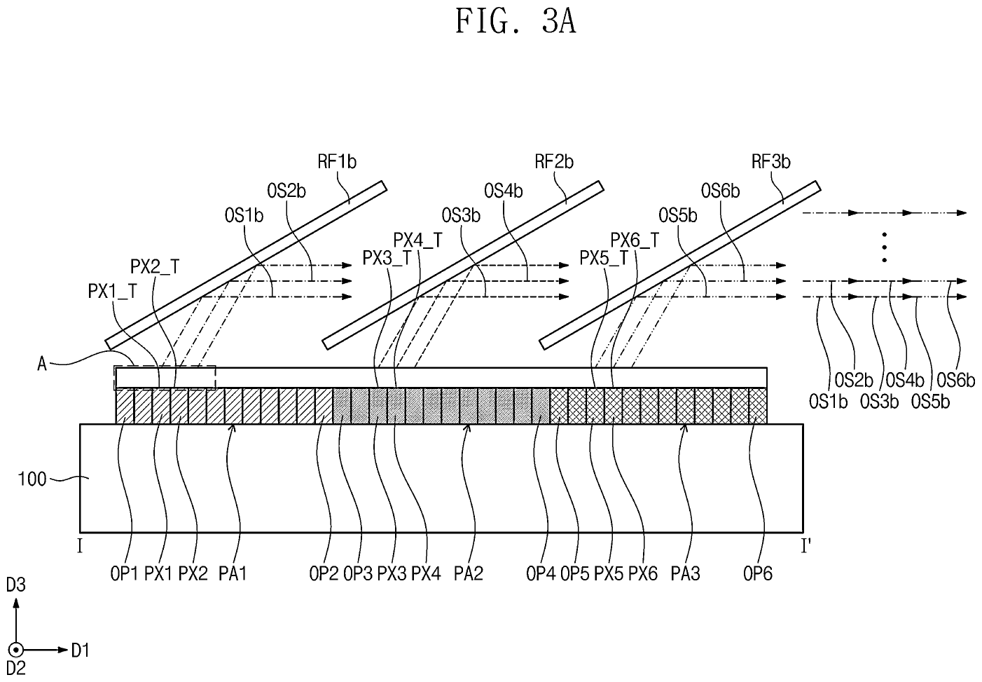

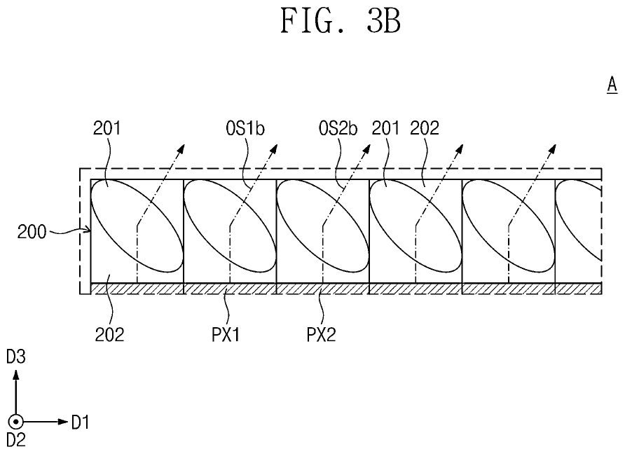

FIG. 3A is a cross-sectional view of a display device according to some embodiments. FIG. 3B is an enlarged view of an area A of FIG. 3A. A display device according to FIGS. 3A and 3B may be similar to the display device according to FIG. 2 except as described below.

Referring to FIGS. 3A and 3B, a path conversion layer 200 may be disposed on the first to third pixel arrays PA1, PA2, and PA3. The path conversion layer 200 may include path conversion lenses 201 and supports 202. In some embodiments, each of the path conversion lens 201 and the supports 202 may include glass. The path conversion lens 201 and the supports 202 may have different refractive indexes.

In some embodiments, the path conversion layer 200 may include a lens array. For example, the path conversion layer 200 may include a Fresnel lens array.

The first pixel PX1 may emit a first optical signal OS1b. The second pixel PX2 may emit a second optical signal OS2b. The third pixel PX3 may emit a third optical signal OS3b. The fourth pixel PX4 may emit a fourth optical signal OS4b. The fifth pixel PX5 may emit a fifth optical signal OS5b. The sixth pixel PX6 may emit a sixth optical signal OS6b.

A path of each of the optical signals OS1b, OS2b, OS3b, OS4b, OS5b, and OS6b may be changed while passing through the path conversion layer 200.

An angle between the traveling path of the first optical signal OS1b emitted from the first pixel PX1 and incident to the path conversion layer 200 and the top surface of the substrate 100 may be greater than an angle between the traveling path of the first optical signal OS1b emitted from the path conversion layer 200 and the top surface of the substrate 100. An angle between the traveling path of the second optical signal OS2b emitted from the second pixel PX2 and incident to the path conversion layer 200 and the top surface of the substrate 100 may be greater than an angle between the traveling path of the second optical signal OS2b emitted from the path conversion layer 200 and the top surface of the substrate 100. An angle between the traveling path of the third optical signal OS3b emitted from the second pixel PX1 and incident to the path conversion layer 200 and the top surface of the substrate 100 may be greater than an angle between the traveling path of the third optical signal OS3b emitted from the path conversion layer 200 and the top surface of the substrate 100. An angle between the traveling path of the fourth optical signal OS4b emitted from the fourth pixel PX4 and incident to the path conversion layer 200 and the top surface of the substrate 100 may be greater than an angle between the traveling path of the fourth optical signal OS4b emitted from the path conversion layer 200 and the top surface of the substrate 100. An angle between the traveling path of the fifth optical signal OS5b emitted from the fifth pixel PX5 and incident to the path conversion layer 200 and the top surface of the substrate 100 may be greater than an angle between the traveling path of the fifth optical signal OS5b emitted from the path conversion layer 200 and the top surface of the substrate 100. An angle between the traveling path of the sixth optical signal OS6b emitted from the sixth pixel PX6 and incident to the path conversion layer 200 and the top surface of the substrate 100 may be greater than an angle between the traveling path of the sixth optical signal OS6b emitted from the path conversion layer 200 and the top surface of the substrate 100.

The first reflector RF1b may reflect the first and second optical signals OS1b and OS2b emitted from the path conversion layer 200. The second reflector RF2b may reflect the third and fourth optical signals OS3b and OS4b emitted from the path conversion layer 200. The third reflector RF3b may reflect the fifth and sixth optical signals OS5b and OS6b emitted from the path conversion layer 200.

The first and second optical signals OS1b and OS2b reflected by the first reflector RF1b, the third and fourth optical signals OS3b and OS4b reflected by the second reflector RF2b, and the fifth and sixth optical signals OS5b and OS6b reflected by the third reflector RF3b may proceed in the first direction D1.

A display device according to some embodiments may include a path conversion layer 200 to reduce the angle between the optical signal from the pixel and the top surface of the substrate 100. Thus, a degree of inclination of bottom surfaces of the first to third reflective layers RF1b, RF2b, and RF3b may be smaller. Therefore, a height of each of the first to third reflective layers RF1b, RF2b, and RF3b in the third direction D3 may be reduced, and miniaturization of the display device may be possible.

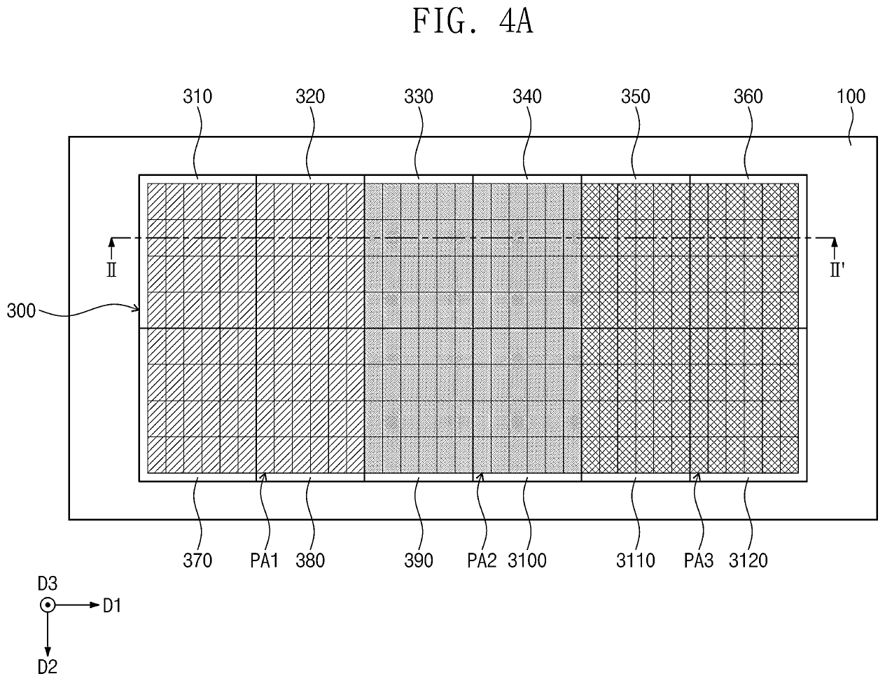

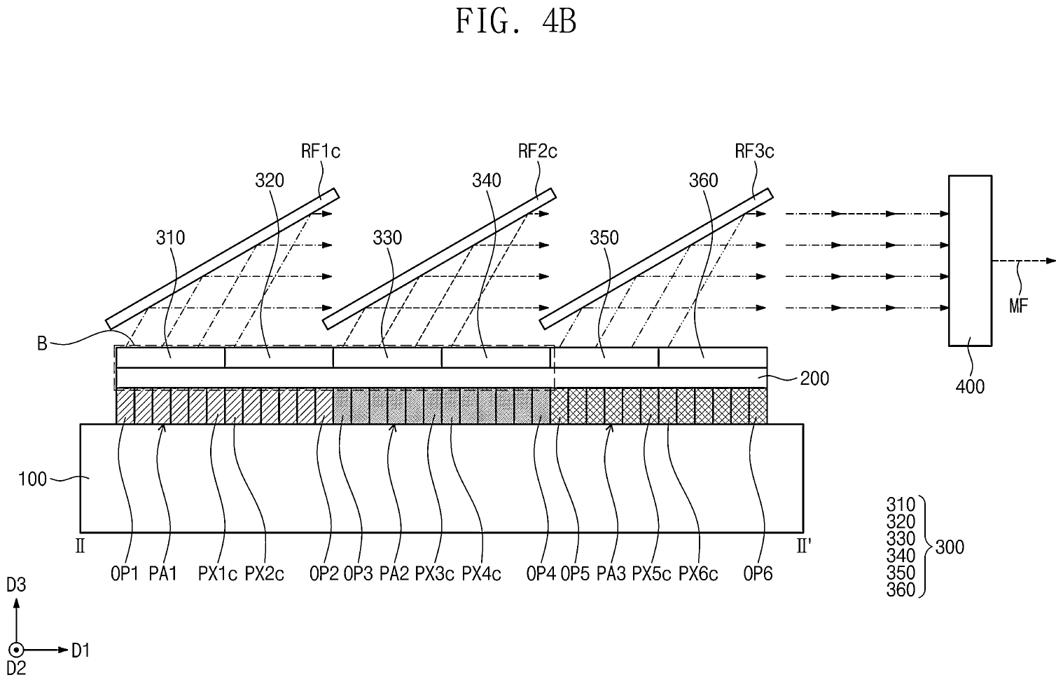

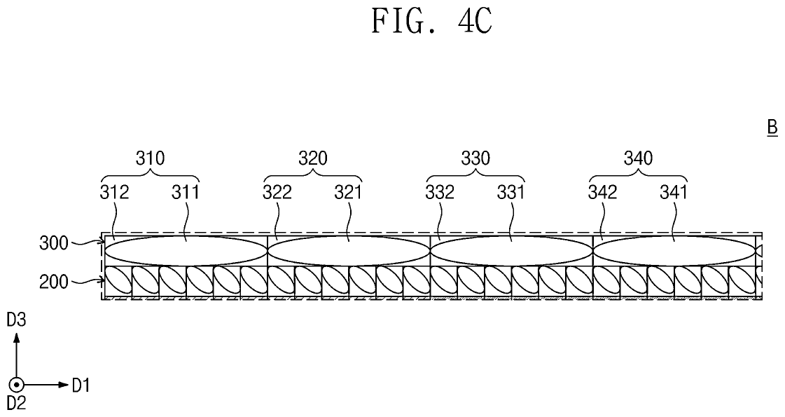

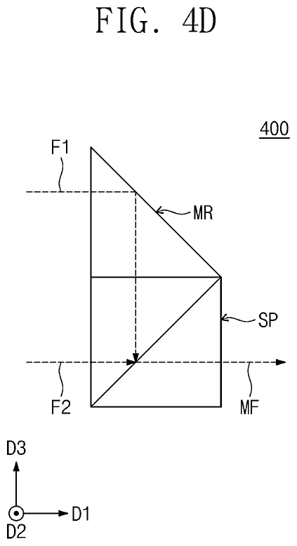

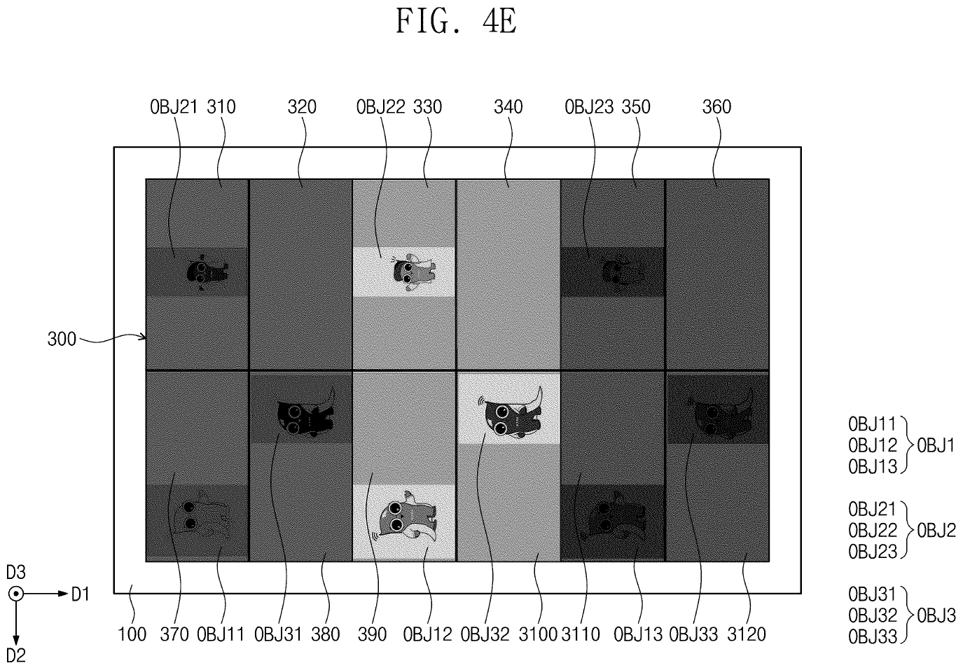

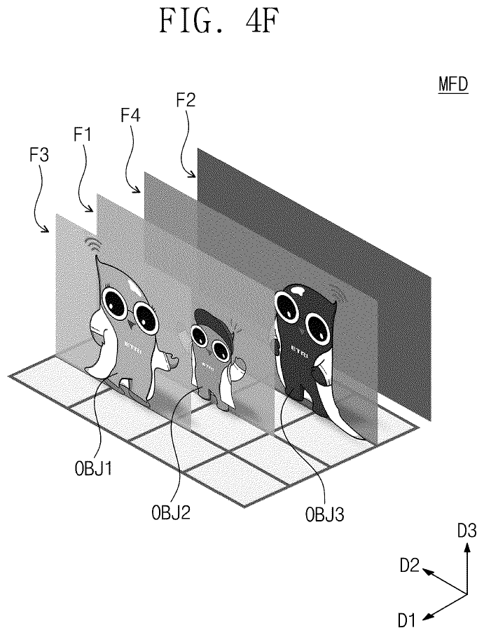

FIG. 4A is a plan view of a display device according to some embodiments. FIG. 4B is a cross-sectional view taken along line II-II′ of FIG. 4A. FIG. 4C is an enlarged view of an area B of FIG. 4B. FIG. 4D is a view illustrating a combiner of the display device according to some embodiments. FIG. 4E is a view illustrating an operation of the display device according to some embodiments. FIG. 4F is a view illustrating an operation of the display device according to some embodiments. The display devices according to FIGS. 4A, 4B, 4C and 4D may be similar to the display devices according to FIGS. 3A and 3B except as described below.

Referring to FIGS. 4A, 4B, and 4C, a focus conversion structure 300 may be disposed on the path conversion layer 200. The focus conversion structure 300 may include a plurality of focus conversion layers arranged in the first direction D1 and the second direction D2. The focus conversion layers may include a first focus conversion layer 310, a second focus conversion layer 320, a third focus conversion layer 330, a fourth focus conversion layer 340, a fifth focus conversion layer 350, a sixth focus conversion layer 360, a seventh focus conversion layer 370, an eighth focus conversion layer 380, a ninth focus conversion layer 390, a tenth focus conversion layer 3100, an eleventh focus conversion layer 3110, and a twelfth focus conversion layer 3120.

The first focus conversion layer 310 may overlap a first pixel PX1c in the third direction D3. The second focus conversion layer 320 may overlap a second pixel PX2c in the third direction D3. The third focus conversion layer 330 may overlap a third pixel PX3c in the third direction D3. The fourth focus conversion layer 340 may overlap a fourth pixel PX4c in the third direction D3.

The seventh focus conversion layer 370 may be adjacent to the first focus conversion layer 310 in an opposite direction to the second direction D2. The eighth focus conversion layer 380 may be adjacent to the second focus conversion layer 320 in an opposite direction to the second direction D2. The ninth focus conversion layer 390 may be adjacent to the third focus conversion layer 330 in an opposite direction to the second direction D2. The tenth focus conversion layer 3100 may be adjacent to the fourth focus conversion layer 340 in an opposite direction to the second direction D2. The eleventh focus conversion layer 3110 may be adjacent to the fifth focus conversion layer 350 in an opposite direction to the second direction D2. The twelfth focus conversion layer 3120 may be adjacent to the sixth focus conversion layer 360 in an opposite direction to the second direction D2.

The first reflector RF1c may overlap the first focus conversion layer 310 and the second focus conversion layer 320 in the third direction D3. The second reflector RF2c may overlap the third focus conversion layer 330 and the fourth focus conversion layer 340 in the third direction D3. The third reflector RF3c may overlap the fifth focus conversion layer 350 and the sixth focus conversion layer 360 in the third direction D3.

The first focus conversion layer 310 may include a first focus conversion lens 311 and a first support 312. The second focus conversion layer 320 may include a second focus conversion lens 321 and a second support 322. The third focus conversion layer 330 may include a third focus conversion lens 331 and a third support 332. The fourth focus conversion layer 340 may include a fourth focus conversion lens 341 and a fourth support 342.

Each of the first focus conversion lens 311 and the third focus conversion lens 331 may have a first focal distance. Each of the second focus conversion lens 321 and the fourth focus conversion lens 341 may have a second focal distance. The fifth focus conversion layer 350 may include a focus conversion lens having the first focal distance. The sixth focus conversion layer 360 may include a focus conversion lens having the second focal distance. Each of the seventh, ninth, and eleventh focus conversion layers 370, 390, and 3110 may include a focus conversion lens having a third focal distance. Each of the eighth, tenth and twelfth focus conversion layers 380, 3100, and 3120 may include a focus conversion lens having a fourth focal distance. The first to fourth focal distances may be different from each other.

Each of traveling directions of light signals incident to the first to fourth focus conversion lenses 311, 321, 331, and 341 and travel directions of light signals emitted by passing through the first to fourth focus conversion lenses 311, 321, 331, and 341 may be the same.

A combiner 400 spaced apart from first to third reflectors RF1c, RF2c, and RF3c in the first direction DI may be provided. The combiner 400 may include a reflective part MR and a splitter part SP. The reflective part MR may include a mirror. The splitter part SP may include a splitter.

Optical signals emitted from the first to third reflectors RF1c, RF2c, and RF3c may be incident to the combiner 400. The combiner 400 may process the incident optical signals to emit multifocal optical signals MF.

A first focus optical signal F1 may be incident to the reflective part MR. In some embodiments, the first focus optical signal F1 may be one of the optical signals transmitted through the first focus conversion layer 310, the third focus conversion layer 330, and the fifth focus conversion layer 350. A second focus optical signal F2 may be incident to the splitter part SP. In some embodiments, the second focus optical signal F2 may be one of the optical signals transmitted through the second focus conversion layer 320, the fourth focus conversion layer 340, and the sixth focus conversion layer 360.

The first focus optical signal F1 may be reflected by the reflection part MR and then be incident to the splitter part SP. The first focus optical signal F1 and the second focus optical signal F2, which are incident to the splitter part SP, may be transmitted through the splitter part SP and then emitted in the first direction D1. A first multifocal optical signal MF1 may be emitted from the splitter part SP. The multifocal optical signal MF may include a first focus optical signal F1 and a second focus optical signal F2, which are emitted from the splitter part SP.

Referring to FIG. 4E, pixels overlapping the seventh focus conversion layer 370 may generate a first color element OBJ11 of a first object OBJ1. Pixels overlapping the ninth focus conversion layer 390 may generate a second color element OBJ12 of the first object OBJ1. Pixels overlapping the eleventh focus conversion layer 3110 may generate a third color element OBJ13 of the first object OBJ1.

Pixels overlapping the first focus conversion layer 310 may generate a first color element OBJ21 of a second object OBJ2. Pixels overlapping the third focus conversion layer 330 may generate a second color element OBJ22 of the second object OBJ2. Pixels overlapping the fifth focus conversion layer 350 may generate a third color element OBJ23 of the second object OBJ2.

Pixels overlapping the eighth focus conversion layer 380 may generate a first color element OBJ31 of a third object OBJ3. Pixels overlapping the tenth focus conversion layer 3100 may generate a second color element OBJ32 of the third object OBJ3. Pixels overlapping the twelfth focus conversion layer 3120 may generate a third color element OBJ33 of the third object OBJ3.

A multifocal display MFD may be provided including a first focus light signal F1, a second focus light signal F2, a third focus light signal F3, and a fourth focus light signal F4. The first focus light signal F1 may include the second object OBJ2. The third focus light signal F3 may include the first object OBJ1. The fourth focus light signal F4 may include the third object OBJ3.

In the display device according to some embodiments, the focus conversion structure 300 may include the focus conversion layers having different focal distances to provide optical signals having different focal planes.

The display device according to some embodiments may include the combiner 400 to display the optical signals having the different focal planes on a single display.

The display device according to the embodiments of the inventive concept may include the optical part that change the traveling direction of the optical signals, and thus, the optical signals emitted from the pixels spaced apart from each other may be emitted to the same area.

The display device according to the embodiments of the inventive concept may emit the optical signals emitted from the pixels spaced apart from each other to the same area, and thus, when the pixels are disposed on the substrate, the pixels that emit the light having the same wavelength range may be disposed adjacent to each other. Thus, the process of forming the pixels on the substrate may be simplified.

In the display device according to the embodiments of the inventive concept, a portion of the reflectors provided in the optical part may include the splitter, and thus, the optical signals reflected by the reflector may be transmitted through another reflector to travel.

The display device according to the embodiments of the inventive concept may include the outer pixels that do not emit the optical signals to the outside of the pixel arrays to maintain the alignment of the pixels, which emit the optical signals, and the optical part.

In the display device according to the embodiments of the inventive concept, some of the reflectors may include the dichroic mirrors, and thus, the wavelength range of the optical signal reflected by each reflector and the wavelength range of the optical signal transmitted through each reflector may be different from each other, so that the intensity of the optical signal transmitted through the reflector may be relatively high.

The display device according to the embodiments of the inventive concept may include the path conversion layer to reduce the angle between the bottom surface of the reflective layer and the top surface of the substrate. Therefore, the distance between the uppermost portion of the reflective layer and the substrate may be reduced to realize the miniaturization of the display device.

The display device according to the embodiments of the inventive concept may include the focus conversion layer to form the multi-focus display.

Although the embodiments of the inventive concept is described with reference to the accompanying drawings, those with ordinary skill in the technical field of the inventive concept pertains will be understood that the present disclosure may be carried out in other specific forms without changing the technical idea or essential features. Therefore, the above-disclosed embodiments are to be considered illustrative and not restrictive.

What is claimed is:

1. A display device comprising:
a first pixel configured to emit a first optical signal;
a second pixel disposed adjacent to the first pixel in a first direction and configured to emit a second optical signal;
a third pixel configured to emit a third optical signal;
a fourth pixel disposed adjacent to the third pixel in the first direction and configured to emit a fourth optical signal; and
an optical part configured to reflect the first to fourth optical signals,
wherein the second pixel and the third pixel are disposed between the first pixel and the fourth pixel,
the first optical signal and the third optical signal are emitted from a first region of the optical part,
the second optical signal and the fourth optical signal are emitted from a second region of the optical part, and
the first region and the second region are spaced apart from each other.

2. The display device of claim 1, wherein each of the first optical signal and the second optical signal comprises light in a first wavelength region, and
each of the third optical signal and the fourth optical signal comprises light in a second wavelength range.

3. The display device of claim 1, further comprising a fifth pixel configured to emit a fifth optical signal and a sixth pixel disposed adjacent to the fifth pixel in the first direction and configured to emit a sixth optical signal,
wherein the fifth pixel is disposed between the fourth pixel and the sixth pixel,
the optical part is configured to reflect the fifth optical signal and the sixth optical signal,
the fifth optical signal is emitted from the first region of the optical part, and
the sixth optical signal is emitted from the second region of the optical part.

4. The display device of claim 3, wherein each of the first optical signal and the second optical signal comprises light in a first wavelength region,
each of the third optical signal and the fourth optical signal comprises light in a second wavelength range, and
each of the fifth optical signal and the sixth optical signal comprises light in a third wavelength range.

5. The display device of claim 1, wherein the optical part is configured to emit the first to fourth optical signals in the first direction.

6. The display device of claim 5, wherein the first pixel is configured to emit the first optical signal in a second direction that intersects the first direction.

7. The display device of claim 1, further comprising a substrate,
wherein the first to fourth pixels are disposed on a top surface of the substrate.

8. A display device comprising:
a first pixel configured to emit a first optical signal;
a second pixel disposed adjacent to the first pixel in a first direction and configured to emit a second optical signal;
a third pixel configured to emit a third optical signal;
a fourth pixel disposed adjacent to the third pixel in the first direction and configured to emit a fourth optical signal; and
an optical part configured to reflect the first to fourth optical signals,
wherein the second pixel and the third pixel are disposed between the first pixel and the fourth pixel,
wherein the optical part comprises:
a first reflector that overlaps the first pixel and the second pixel and is spaced apart from the first pixel and the second pixel in the second direction; and
a second reflector that overlaps the third pixel in the second direction and is spaced apart from the third pixel and the fourth pixel in the second direction,
wherein the second direction intersects the first direction.

9. The display device of claim 8, further comprising a substrate,
wherein the first to fourth pixels are disposed on a top surface of the substrate, and
a bottom surface of the first reflector is inclined with respect to the top surface of the substrate.

10. The display device of claim 9, wherein a bottom surface of the second reflector is parallel to the bottom surface of the first reflector.

11. The display device of claim 8, further comprising a path conversion layer disposed between the first pixel and the first reflector,
wherein a traveling direction of the first optical signal incident to the path conversion layer and a traveling direction of the first optical signal emitted from the path conversion layer are different from each other.

12. The display device of claim 8, wherein the second reflector comprises a splitter.

13. The display device of claim 8, wherein the first reflector is configured to reflect the first optical signal and the second optical signal, and
the second reflector is configured to reflect the third optical signal and the fourth optical signal.

14. A display device comprising:
a substrate;
a first pixel, a second pixel, a third pixel, a fourth pixel, a fifth pixel, and a sixth pixel, which are disposed on the substrate; and
a first outer pixel, a second outer pixel, a third outer pixel, a fourth outer pixel, a fifth outer pixel, and a sixth outer pixel,
wherein the first pixel and the second pixel are disposed between the first outer pixel and the second outer pixel,
the third pixel and the fourth pixel are disposed between the third outer pixel and the fourth outer pixel,
the fifth pixel and the sixth pixel are disposed between the fifth outer pixel and the sixth outer pixel,
the second outer pixel and the third outer pixel are adjacent to each other in a first direction,
the fourth outer pixel and the fifth outer pixel are adjacent to each other in the first direction,
each of the first and second pixels is configured to emit an optical signal comprising light in a first wavelength range,
each of the third and fourth pixels is configured to emit an optical signal comprising light in a second wavelength range, and
each of the fifth and sixth pixels is configured to emit an optical signal comprising light in a third wavelength range.

15. The display device of claim 14, further comprising a first focus conversion layer overlapping the first pixel and a second focus conversion layer overlapping the second pixel,
wherein the first focus conversion layer comprises a first lens, and
the second focus conversion layer comprises a second lens,
wherein the first lens and the second lens have focus distances different from each other.

16. The display device of claim 15, further comprising a third focus conversion layer overlapping the third pixel and a fourth focus conversion layer overlapping the fourth pixel,
wherein the third focus conversion layer comprises a third lens, and
the fourth focus conversion layer comprises a fourth lens,
wherein the first lens and the third lens have the same focus distance, and
the second lens and the fourth lens have the same focus distances-.

17. The display device of claim 16, further comprising:
a first reflector overlapping the first focus conversion layer and the second focus conversion layer; and
a second reflector overlapping the third focus conversion layer and the fourth focus conversion layer.

18. The display device of claim 16, further comprising a path conversion layer between the first pixel and the first focus conversion layer and between the third pixel and the third focus conversion layer,
wherein the path conversion layer comprises a lens array.
